(19) United States
(12) Patent Application Publication
(10) Pub. No.: US 2008/0259980 A1
(43) Pub. Date: Oct. 23, 2008

(54) Semiconductor Light Emitting Device Including Oxide Layer

(75) Inventors: Jonathan J. Wierer, Pleasanton, CA (US); Michael R. Krames, Los Altos, CA (US)

Correspondence Address: PATENT LAW GROUP LLP, 2635 NORTH FIRST STREET, SUITE 223, SAN JOSE, CA, 95134, US

(73) Assignee: PHILIPS LUMILEDS LIGHTING COMPANY, LLC, San Jose, CA (US)

(21) Appl. No.: 11/737,624

(22) Filed: Apr. 19, 2007

(51) Int. Cl. H01S 5/32

(52) U.S. Cl. 372/44.01

(57) ABSTRACT

A device includes a semiconductor structure comprising a III-nitride light emitting layer disposed between an n-type region and a p-type region. The semiconductor structure is grown over an oxide layer disposed between first and second III-nitride layers. The oxide layer may at least partially relieve the strain in the light emitting layer by increasing the in-plane lattice constant of the template on which the light emitting layer is grown. The oxide layer may be formed by growing an AlInN layer in the device, etching a trench to expose the AlInN layer, then oxidizing the AlInN layer.

### BACKGROUND

1. Field of Invention

This invention relates to a semiconductor light emitting device including an oxide layer, more particularly to a III-nitride light emitting device including an oxide layer for strain relief.

2. Description of Related Art

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions.

### SUMMARY

In accordance with embodiments of the invention, a device includes a semiconductor structure comprising a III-nitride light emitting layer disposed between an n-type region and a p-type region. The semiconductor structure is grown over an oxide layer disposed between first and second III-nitride layers. The oxide layer may at least partially relieve the strain in the light emitting layer by allowing the second layer, over which the light emitting layer is grown, to at least partially relax to a larger lattice constant. The oxide layer may be formed by growing an AlInN layer in the device, etching a trench to expose the AlInN layer, then oxidizing the AlInN layer.

### BRIEF DESCRIPTION OF THE DRAWINGS

FIG. 1 is a cross sectional view of a structure including a layer that is later oxidized sandwiched between two III-nitride layers.

FIG. 2 is a cross sectional view of the structure of FIG. 1 after forming at least one via or trench and forming an oxide layer.

FIG. 3 is a cross sectional view of the structure of FIG. 2 after growing III-nitride device layers including a light emitting layer.

FIG. 4 is a cross sectional view of a structure including multiple oxide layers alternating with III-nitride layers, which may act as a distributed Bragg reflector.

FIG. 5 is a cross sectional view of a portion of a III-nitride device mounted in flip chip configuration on a mount.

FIG. 6 is a cross sectional view of a resonant cavity formed by a process such as chemical mechanical polishing.

FIG. 7 is a cross sectional view of a resonant cavity formed by etching to a self-aligned etch-stop layer such as an oxide layer.

FIG. 8 is an exploded view of a packaged light emitting device.

### DETAILED DESCRIPTION

The performance of a semiconductor light emitting device may be gauged by measuring the external quantum efficiency, which measures the number of photons extracted from the device per electron supplied to the device. As the current density applied to a conventional III-nitride light emitting device increases, the external quantum efficiency of the device initially increases, then decreases. As the current density increases past zero, the external quantum efficiency increases, reaching a peak at a given current density (for example, at about 10 A/cm² for some devices). As current density increases beyond the peak, the external quantum efficiency initially drops quickly, then the decrease slows at higher current density (for example, beyond 200 A/cm² for some devices). The quantum efficiency of a device also decreases as the InN composition in the light emitting region increases and as the wavelength of emitted light increases.

Since native III-nitride growth substrates are generally expensive, not widely available, and impractical for growth of commercial devices, III-nitride devices are often grown on sapphire (Al₂O₃) or SiC substrates. III-nitride devices often include GaN, InGaN, and AlGaN layers. For devices that emit visible light, InGaN light emitting layers are often grown over GaN. There is a large lattice mismatch between GaN and the InGaN light emitting layers, resulting in strain in the light emitting layers. This strain limits the thickness and In percentage in the InGaN quantum well. Increasing the thickness of the light emitting layers in the device may increase the current density where the peak in efficiency occurs. However, as the thickness and InN composition in the light emitting layers increases, the strain in the light emitting layers also increases. Reducing the strain in the light emitting layers may permit, for a given efficiency, growth of thicker light emitting layers and/or higher InN composition light emitting layers.

As used herein, an “in-plane” lattice constant refers to the actual lattice constant of a layer within the device, and a “bulk” lattice constant refers to the lattice constant of relaxed, free-standing material of a given composition. The amount of strain in a layer is defined in Eq. (1).

strain=ε=(aᵢₙ₋ₚₗₐₙₑ−a_{bulk})/a_{bulk} (1)

Note that strain, ε, in Eq. (1) can be either positive or negative, i.e., ε>0 or ε<0. In an unstrained film, aᵢₙ₋ₚₗₐₙₑ=a_{bulk}, so ε=0 in Eq. (1). A film where ε>0 is said to be under tensile strain, or under tension, while a film where ε<0 is said to be under compressive strain, or under compression. Examples of tensile strain include a strained AlGaN film grown over unstrained GaN, or a strained GaN film grown over unstrained InGaN. In both cases, the strained film has a bulk lattice constant that is smaller than the bulk lattice constant of the unstrained layer on which it is grown, so the in-plane lattice constant of the strained film is stretched to match that of the unstrained layer, giving ε>0 in Eq. (1). Examples of compressive strain include a strained InGaN film grown over unstrained GaN, or a strained GaN film grown over unstrained AlGaN. In both cases, the strained film has a bulk lattice constant that is larger than the bulk lattice constant of the unstrained layer on which it is grown, so the in-plane lattice constant of the strained film is compressed to match that of the unstrained layer, giving ε<0 in Eq. (1).

In a tensile film, the strain pulls the atoms apart from one another in order to increase the in-plane lattice constant. Tensile strain is often undesirable, because the film can respond to the tensile strain by cracking, which decreases the strain in the film, but compromises the structural and electrical integrity of the film. In a compressive film, the strain pushes the atoms together. This effect can reduce the incorporation of large atoms such as indium in an InGaN film, for example, or can negatively impact the material quality of the InGaN active layer in an InGaN LED. In many cases, tensile and compressive strain are both undesirable, and it is beneficial to decrease the tensile or compressive strain in the various layers of the device. In such cases, it is more convenient to refer to the absolute value, or magnitude of the strain, as defined in Eq. (2). As used herein, the term “strain” shall be understood to mean the absolute value, or magnitude of the strain, as defined in Eq. (2).

strain=|ε|=|(aᵢₙ₋ₚₗₐₙₑ−a_{bulk})|/a_{bulk} (2)

In accordance with embodiments of the invention, an oxide layer is included in a III-nitride light emitting device. The oxide layer may reduce the strain in some of the device layers, particularly in the light emitting layer.

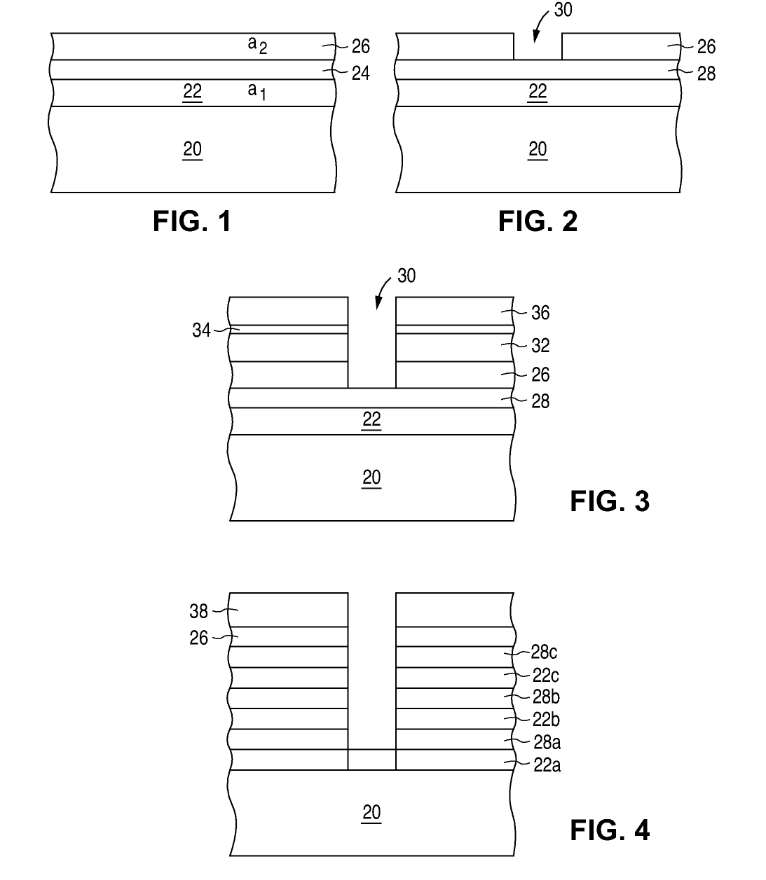

FIGS. 1-3 illustrate one example of how to fabricate a III-nitride light emitting device including an oxide layer. FIG. 1 is a cross sectional view of a portion of a device. An optional first III-nitride region 22, generally GaN, having a bulk lattice constant a,, is grown over any suitable substrate 20. First III-nitride region 22 is generally formed of a material that readily nucleates on the substrate 20. Besides GaN, first III-nitride region 22 may be InN, InGaN, AlGaN, AlN, or AlInGaN. In some embodiments, first III-nitride region 22 may be omitted, and to-be-oxidized region 24 may be grown directly on substrate 20.

A region 24 of to-be-oxidized material is grown over GaN region 22. Region 24 may have thickness, for example, between 25 and 500 nm. A thicker layer may oxidize more quickly than a thinner layer. In some embodiments, the composition of region 24 is selected to be a reasonably close lattice-match to the material in region 22, which is generally GaN. Alternatively, region 24 is at least partially strained, but is grown a thickness less than the critical thickness, so the material does not relax. Lattice matching region 24 to region 22 facilitates growth and may improve the material quality of subsequently grown region 26. In some embodiments, region 24 is an AlInN layer, for example with an AlN composition greater than 80%. AlInN may be grown by, for example, atmospheric pressure metal-organic vapor-phase epitaxy, or in a horizontal atmospheric pressure metal-organic chemical-vapor deposition reactor. An AlInN layer with 82% AlN is lattice-matched to GaN. If region 22 is AlGaN, as the AlN composition in region 22 increases, the AlN composition in region 24 may increase, to maintain the lattice match between regions 22 and 24.

A region of material 26 with a bulk lattice constant a₂ larger than bulk lattice constant a, of region 22 is grown over to-be-oxidized region 24. For example, region 26 may be InGaN, generally with a bulk lattice constant between the smaller bulk lattice constant of region 22 and the larger bulk lattice constant of a later-grown light emitting layer. The thickness of region 26 is kept below the critical thickness, i.e. the thickness at which strained region 26 relaxes. The critical thickness depends on the composition of region 26, and the magnitude of the bulk lattice constant mismatch between region 26 and region 22. As the magnitude of the difference in bulk lattice constant between region 22 and region 26 increases, the critical thickness decreases. In some examples, an In_{0.05}Ga_{0.95}N region 26 may be grown to a thickness up to 100 nm, an In_{0.1}Ga_{0.9}N region 26 may be grown to a thickness up to 50 nm, and an In_{0.16}Ga_{0.84}N region 26 may be grown to a thickness up to 30 nm.

As illustrated in FIG. 2, one or more vias or channels 30 is etched through region 26 to expose to-be-oxidized region 24, shown in FIG. 1. Vias 30 may extend into or through region 24. The size of the channels or vias are selected to balance the time required to oxidize region 24, which favors spacing channels closer together, with the amount of material lost to etching or damaged by etching, which favors spacing channels further apart. In some embodiments, only a small amount of material on the edge of the wafer is etched away to reveal to-be-oxidized region 24, which is then oxidized from the edge of the wafer toward the center. In some embodiments, a grid of channels is formed that outlines individual devices in the undiced wafer. For example, the grid of channels may define devices on the order of square millimeters, such as 1 mm by 1 mm, 1 mm by 2 mm, or 2 mm by 2 mm. In other embodiments, the vias or channels are spaced more closely than a device length apart, for example on the order of tens or hundreds of microns apart.

Region 24 is then oxidized into oxide region 28, shown in FIG. 2. As described above, region 24 may be, for example, an AlInN layer with an AlN composition of at least 80%. Such a layer may be oxidized by exposing the wafer, to which a small piece of In may be alloyed for current access, to an electrolyte solution of nitrilotriacetic acid dissolved in a 0.3M solution of potassium hydroxide in water, to reach a pH value of 8.5. A small current density of 20 μA/cm² is applied at a threshold voltage of about 3 V. The oxidation travels laterally, for example at a rate between 5 and 20 μm per hour. After oxidation, oxide region 28 is an amorphous oxide layer AlₓO_{y} or AlₓIn_{y}O_{z}. At least some of the In in the AlInN layer generally remains in the oxide layer after oxidation. The In may or may not oxidize. Since III-nitride region 26 has a larger bulk lattice constant than III-nitride region 22, the oxidation process or the presence of amorphous oxide region 24 may permit region 26 to at least partially relax, expanding or contracting the in-plane lattice constant of region 26 relative to the in-plane lattice constant of region 22.

In FIG. 3, III-nitride device layers including an n-type region 32, a light emitting region 34, and a p-type region 36, are grown over partially relaxed region 26.

N-type region 32 may include multiple layers of different compositions and dopant concentration including, for example, preparation layers such as buffer layers or nucleation layers which may be n-type or not intentionally doped, release layers designed to facilitate later release of the growth substrate or thinning of the semiconductor structure after substrate removal, and n- or even p-type device layers designed for particular optical or electrical properties desirable for the light emitting region to efficiently emit light.

Light emitting region 34 is grown over n-type region 32. Examples of suitable light emitting regions include a single thick or thin light emitting layer and a multiple quantum well light emitting region including multiple thin or thick quantum well light emitting layers separated by barrier layers. For example, a multiple quantum well light emitting region may include multiple InGaN light emitting layers, each with a thickness of 25 Å or less, separated by GaN or InGaN barriers, each with a thickness of 100 Å or less.

In some embodiments, the thickness of each of the light emitting layers in the device is thicker than 50 Å. In some embodiments, the light emitting region of the device is a single, thick light emitting layer with a thickness between 50 and 600 Å, more preferably between 100 and 250 Å. The optimal thickness may depend on the number of defects within the light emitting layer. The concentration of defects in the light emitting region is preferably limited to less than 10⁹ cm⁻², more preferably limited to less than 10⁸ cm⁻², more preferably limited to less than 10⁷ cm⁻², and more preferably limited to less than 10⁶ cm⁻².

In some embodiments, at least one light emitting layer in the device is doped with a dopant such as Si to a dopant concentration between 1×10¹⁸ cm⁻³ and 1×10²⁰ cm⁻³. Si doping may reduce the in-plane a lattice constant in the light emitting layer, further reducing the strain in the light emitting layer. In some embodiments, the light emitting layer or layers are not intentionally doped.

P-type region 36 is grown over light emitting region 34. Like the n-type region, the p-type region may include multiple layers of different composition, thickness, and dopant concentration, including layers that are not intentionally doped, or n-type layers.

The composition and thickness of n-type region 32 and p-type region 36 may depend on the composition of region 26 over which n-type region 32 is grown. The composition of region 26 is selected to expand the in-plane lattice constant as much as possible, in order to reduce the strain in the device layers, particularly in the light emitting region. If region 26 and light emitting region 34 have the same bulk lattice constant, region 26 completely relaxes during or after oxidation of layer 28, and all layers between region 26 and light emitting region 34 have the same in-plane lattice constant as region 26, there may be no strain in light emitting region 34.

In some embodiments, it may not be practical to completely eliminate strain in the light emitting region. In order to confine the electrons and holes that combine to create light within the light emitting region, the light emitting region is sandwiched between layers of higher band gap. In devices formed from binary and ternary III-nitride layers such as GaN and InGaN, the higher band gap layers sandwiching the light emitting region have less InN than the light emitting region, which means the higher band gap layers have smaller bulk lattice constants than the light emitting region. As a result, if the bulk lattice constants of region 26 and light emitting region 34 are matched to eliminate all strain in the light emitting region, these higher band gap layers sandwiching the light emitting region will be under tensile strain. As the thickness of a layer under tensile strain increases, the layer will eventually crack, or relax, creating defects. Thus, the amount of tensile strain may undesirably limit the thickness to which n- and p-type regions 32 and 36 may be grown.

In the case of an InGaN region 26 and InGaN light emitting layer, the bulk lattice constant and therefore the composition of region 26 is selected to include as much InN as possible in order to reduce the strain in the light emitting layer as much as possible, while keeping the InN composition in region 26 low enough that n-type region 32 and p-type region 36 can be grown without cracking at compositions suitable for confining carriers and thicknesses suitable for spreading current from the n- and p-contacts. In some embodiments, n-type region 32 is at least 300 nm thick, such that current spreads efficiently through the n-type region for a distance of at least 50 μm.

In some embodiments, n-type region 32 may include one or more InGaN layers, or may include one or more Si-doped layers, in order to reduce the amount of tensile strain and thereby increase the thickness at which n-type region 32 may be grown without cracking. In some embodiments, n-type layer 32 has the same composition as region 26, thus n-type layer 32 may be grown to arbitrary thickness, since there is little or no strain in n-type layer 32. The light emitting layers may also have the same composition as region 26 and n-type region 32, such that there is little or no strain in the light emitting region. Alternatively, the light emitting layers may have a different composition than n-type region 32. The presence of some strain in the light emitting region may improve the internal quantum efficiency and therefore the performance of some device structures.

In a first example, first III-nitride region 22 is GaN, region 26 is In_{0.05}Ga_{0.95}N region 26 up to 100 nm thick, n-type region 32 is a single In_{0.05}Ga_{0.95}N layer, and light emitting region 34 includes at least one In_{0.1}Ga_{0.9}N quantum well layer, a light emitting layer that typically emits blue light. The strain in the In_{0.1}Ga_{0.9}N quantum well layer may be less than the strain in a quantum well layer of the same composition and thickness grown in a conventional device.

In a second example, first III-nitride region 22 is GaN, region 26 is In_{0.1}Ga_{0.9}N region 26 up to 50 nm thick, n-type region 32 is a single In_{0.1}Ga_{0.9}N layer, and light emitting region 34 includes at least one In_{0.2}Ga_{0.8}N quantum well layer, a light emitting layer that typically emits green light. The strain in the In_{0.2}Ga_{0.8}N quantum well layer may be less than the strain in a quantum well layer of the same composition and thickness grown in a conventional device.

In a third example, first III-nitride region 22 is GaN, region 26 is In_{0.1}Ga_{0.9}N region 26 up to 50 nm thick, n-type region 32 is a single In_{0.1}Ga_{0.9}N layer, and light emitting region 34 includes at least one In_{0.1}Ga_{0.9}N quantum well layer, a light emitting layer that typically emits blue light. The quantum well layer is sandwiched by thin barrier layers with a larger band gap than the quantum well layer. The barrier layers may be InGaN with a lower InN composition than the quantum well layer, or GaN, grown to a thickness below the critical thickness. Since the In_{0.1}Ga_{0.9}N quantum well layer has the same composition as region 26 and n-type layer 32, the strain in a quantum well layer may be eliminated.

In the structure illustrated in FIG. 4, multiple oxide layers 28a, 28b, and 28c, alternate with III-nitride layers 22a, 22b, and 22c. The structure shown in FIG. 4 may be formed by growing AlInN layers alternating with InGaN or GaN layers, then oxidizing the AlInN layers as described above. The III-nitride layer 22a, 22b, and 22c may each have the same composition, or may have different compositions. In some embodiments, the InN composition may be increased from a lowest InN composition in the layer closest to the substrate to a highest InN composition in the layer furthest from the substrate, in order to progressively reduce the strain in subsequently grown layers. In one example, layer 22a closest to substrate 20 is GaN, layer 22b is In_{0.15}Ga_{0.85}N, layer 22c is In_{0.3}Ga_{0.7}N, and layer 26 is In_{0.45}Ga_{0.55}N. The use of multiple oxide layers may permit higher InN compositions in the n-type region and in the light emitting layers than a single oxide layer.

The oxide layers have a refractive index of about 1.8, and the InGaN or GaN layers have a refractive index of about 2.4. The contrast in index of refraction forms a distributed Bragg reflector. The reflector may be used in a device incorporating a resonant cavity, such as a resonant cavity LED, a photonic crystal LED, a vertical cavity surface-emitting laser, or an edge-emitting laser.

Though the above examples describe III-nitride devices, in some embodiments of the invention other semiconductor material systems may be used. In general, a first semiconductor region 22 is grown, followed by a region 24 of different composition which is reasonably lattice-matched to region 22 and which can be oxidized. A third region 26 is grown that is lattice-mismatched from regions 22 and 24. Region 26 may be thinner than the critical thickness. Region 24 is oxidized, such that region 26 at least partially relaxes to its bulk lattice constant. Subsequently grown layers conform to the in-plane lattice constant of relaxed region 26. Such a structure can be implemented in other III-V and II-VI semiconductor material systems. In particular, region 24 may be a high Al-bearing compound such as AlInGaAs, AlAs, AlGaAs, AlInAs, AlInGaSb, AlAsSb, AlSb, AlGaSb, AlInSb, AlInGaP, AlP, AlGaP, and AlInP. Thin, strained region 26 may be a III-V semiconductor compound such as AlInGaP, InGaP, GaP, InP, GaAsP, AlInGaAsP, AlInGaAs, InGaAs InAs,GaAs, AlGaInSb, GaSb, InSb, GaInSb, and GaSbAs, or a II-VI semiconductor such as ZnO, ZnS, ZnSe, ZnTe, CdS, CdSe, CdTe, HgS, HgSe, HgTe, and any combination thereof.

Oxide layer 28 may also be used as an etch-stop layer to form a resonant cavity of uniform thickness. FIG. 6 shows a portion of a resonant cavity formed by a conventional process that results in a flat surface. In the structure shown in FIG. 6, device layers 32, 34, and 36 are grown over oxide layer 28 and III-nitride layer 26, as illustrated in FIG. 3. A reflective p-contact 42 is formed over p-type region 36, then the device is flipped, resulting in the orientation shown in FIG. 6. The growth substrate, oxide layer, and a portion of III-nitride layer 26 are removed to form a resonant cavity.

Due to the lattice mismatch between the growth substrate on which the epitaxial layers are grown and between the epitaxial layers themselves, it is difficult to grow flat III-nitride layers. The presence of crystal defects generally results in III-nitride layers with an uneven surface, as illustrated by device layers 32, 34, and 36 in FIG. 6. The surfaces of the III-nitride layers may have a cross section including peaks separated by valleys. The “peaks” are slanted crystal planes, separated by the “valleys” formed by steps between the individual planes. The planes may be, for example, 1 to 150 microns long, and are often about 100 microns long. The steps may have a height, for example, on the order of about λ/4, where X is the wavelength in the crystal of light emitted by active region 34. For example, the steps may have a height between about 15 nm and about 100 nm. Region 32, 34, and 36 have the same peak-and-valley surface, caused by initial growth conditions of region 22 and substrate offcut, as illustrated at the interfaces between light emitting region 34 and p-type region 36, and between light emitting region 34 and n-type region 32. Conventional thinning processes such as conventional etching, grinding, or chemical mechanical polishing typically result in a flat surface, as illustrated on the top surface of remaining region 26 shown in FIG. 6. Accordingly, forming a resonant cavity device by conventional processes results in a cavity with one uneven surface (the interface between p-type region 36 and p-contact 42, resulting from growth) and one flat surface (the interface between region 26 and the top mirror, which is not shown, resulting from etching or chemical mechanical polishing). The difference in the surfaces on either side of the resonant cavity results in variations in the cavity thickness as illustrated by arrows 46 and 48. The cavity is thicker at arrow 46 than at arrow 48. As a result, only portions of the cavity are appropriately tuned. Such variations can decrease the efficiency of the device.

The thickness of the resonant cavity may be kept constant by using oxide layer 28, shown in FIG. 3, as an etch stop layer. The rough surface of the epitaxial structure is begins with the initial growth of region 22 and is replicated in all layers (26, 32, 34, and 36) grown over region 22, as illustrated in FIG. 7. The device is thinned by a process that terminates on oxide layer 28, then oxide layer 28 may be selectively removed, resulting in a cavity with a constant thickness, since the top cavity surface is identical to the bottom cavity surface. FIG. 7 illustrates a portion of a device where the cavity is thinned by a process that terminates on an oxide layer. The oxide layer may remain part of the device or may be selectively removed. A wet chemical such as hydrofluoric acid (HF) can be used to etch the oxide layer without causing damage to InGaN layers. As illustrated in FIG. 7, both surfaces of the cavity, the interface between region 26 and an optional overlying mirror (not shown) and the interface between p-type region 36 and p-contact 42, have the same surface shape, resulting in a cavity of constant thickness. In some embodiments, at any point in the cavity, the thickness of the cavity varies less than λ/8 from an average thickness of the cavity, or less than 5% from the average thickness of the cavity.

Oxide layer 28 may also be etched to remove the growth substrate. Etching oxide layer 28 to remove the growth substrate may cause less damage to the device layers than substrate removal processes such as laser melting. For example, HF may be used to etch an aluminum oxide layer oxidized from AlInN, as described above.

The light emitting layers in the embodiments described above may have larger in-plane a-lattice constants than light emitting layers grown in conventional devices, which typically have in-plane a-lattice constants no larger than 3.1885 Å. Growth of the light emitting layer over a strain-relieved layer at least partially relaxed by an oxide layer may increase the in-plane lattice constant to greater than 3.189 Å. In some embodiments, the in-plane a-lattice constant in the light emitting layer may be increased to at least 3.195 Å, more preferably to at least 3.2 Å. In some embodiments, in particular when multiple oxide layers are used, the in-plane lattice constant in the light emitting layer may be increased to 3.53 Å, the bulk lattice constant of InN.

An InGaN layer that emits blue light may have the composition In_{0.12}Ga_{0.88}N, a composition with a bulk lattice constant of 3.23 Å. In the case of a conventional In_{0.12}Ga_{0.88}N layer, the strain is (3.189 Å-3.23 Å)/3.23 Å, about 1.23%. If a light emitting layer of the same composition is grown according to the embodiments described above, the strain may be reduced or eliminated. In some embodiments of the invention, the strain in the light emitting layer of a device emitting light between 430 and 480 nm may be reduced to less than 1%, and more preferably to less than 0.5%. An InGaN layer that emits cyan light may have the composition In_{0.16}Ga_{0.84}N, a composition with strain of about 1.7% when grown in a conventional device. In some embodiments of the invention, the strain in the light emitting layer of a device emitting light between 480 and 520 nm may be reduced to less than 1.5%, and more preferably to less than 1%. An InGaN layer that emits green light may have the composition In_{0.2}Ga_{0.8}N, a composition with a free standing lattice constant of 3.26 Å, resulting in strain of about 2.1% when grown in a conventional device. In some embodiments of the invention, the strain in the light emitting layer of a device emitting light between 520 and 560 nm may be reduced to less than 2%, and more preferably to less than 1.5%.

The semiconductor structures illustrated and described above may be included in any suitable configuration of a light emitting device, such as a device with contacts formed on opposite sides of the device or a device with both contacts formed on the same side of the device. When both contacts are disposed on the same side, the device may be formed either with transparent contacts and mounted such that light is extracted either through the same side on which the contacts are formed, or with reflective contacts and mounted as a flip chip, where light is extracted from the side opposite the side on which the contacts are formed. In devices where light is extracted through the surface on which the contacts are formed, since current does not spread as readily in p-type III-nitride material as in n-type III-nitride material, the contact may include a small, thick, absorbing metal bond pad formed over a thin, transparent current spreading layer. The current spreading layer may be, for example, a thin layer of Ni and/or Au, indium tin oxide, Cu-doped InO, ZnO, Ga-doped ZnO, or any other suitable doped, transparent oxide.

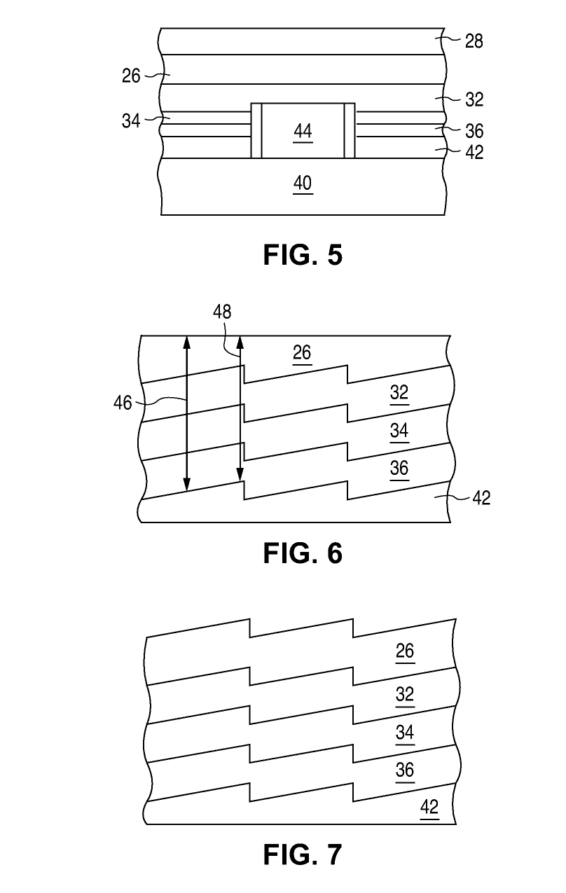

FIG. 5 illustrates a portion of one example of a suitable configuration, a flip chip device from which the growth substrate has been removed. A portion of p-type region 36 and light emitting region 34 is removed to form a mesa that exposes a portion of n-type region 32. Though one via exposing n-type region 32 is shown in FIG. 5, it is to be understood that multiple vias may be formed in a single device. N- and p-contacts 44 and 42 are formed on the exposed parts of n-type region 32 and p-type region 36, for example by evaporating or plating. Contacts 42 and 44 may be electrically isolated from each other by air or a dielectric layer.

After contact metals 42 and 44 are formed, a wafer of devices may be diced into individual devices, then each device may be flipped relative to the growth direction and mounted on a mount 40, in which case mount 40 may have a lateral extent larger than that of the device. Alternatively, a wafer of devices may be connected to a wafer of mounts, then diced into individual devices. Mount 40 may be, for example, semiconductor such as Si, metal, or ceramic such as AlN, and may have at least one metal pad (not shown) which electrically connects to p-contacts 42 and at least one metal pad (not shown) which electrically connects to the n-contacts 44. Interconnects (not shown) such as solder or gold stud bumps, connect the semiconductor device to mount 40. Inter-metal dielectrics may be formed on or within mount 40 to electrically isolate the p-type and n-type current paths.

After mounting, the growth substrate (shown in FIGS. 3 and 4) is removed by a process suitable to the substrate material, such as etching or laser melting. For example, oxide region 28 can be selectively etched away to lift off the substrate. A rigid underfill may be provided between the device and mount 40 before or after mounting to support the semiconductor layers and prevent cracking during substrate removal. A portion of the semiconductor structure may be removed by thinning after removing the substrate. For example, oxide region 28 and III-nitride region 26 may remain in the finished device, as shown in FIG. 5, or they may be removed by thinning. The exposed surface of the semiconductor structure may be roughened, for example by an etching process such as photoelectrochemical etching or by a mechanical process such as grinding. Roughening the surface from which light is extracted may improve light extraction from the device. Alternatively, a photonic crystal structure may be formed in the top surface of the semiconductor structure exposed by removing the grown substrate. A structure such as a phosphor layer or secondary optics known in the art such as dichroics or polarizers may be applied to the emitting surface.

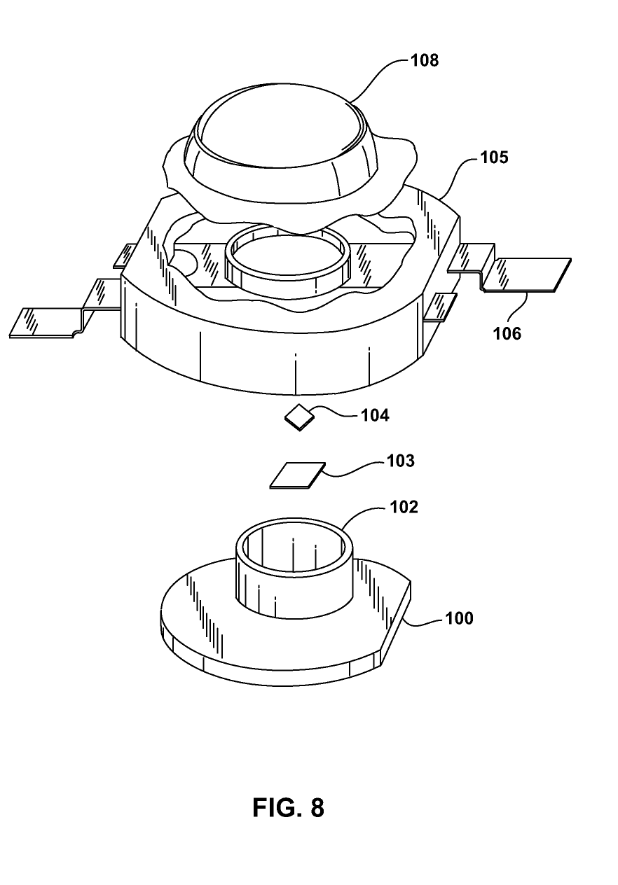

FIG. 8 is an exploded view of a packaged light emitting device, as described in more detail in U.S. Pat. No. 6,274,924. A heat-sinking slug 100 is placed into an insert-molded leadframe. The insert-molded leadframe is, for example, a filled plastic material 105 molded around a metal frame 106 that provides an electrical path. Slug 100 may include an optional reflector cup 102. The light emitting device die 104, which may be any of the devices described in the embodiments above, is mounted directly or indirectly via a thermally conducting submount 103 to slug 100. A cover 108, which may be an optical lens, may be added.

Though the embodiments above describe reducing the strain in a device with InGaN light emitting layers, the techniques and structures described herein may also be used to reduce strain in a device with AlGaN light emitting layers, which typically emit UV light.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A device comprising:
a semiconductor structure comprising a III-nitride light emitting layer disposed between an n-type region and a p-type region; and
an oxide layer disposed between first and second III-nitride layers;
wherein one of the p-type region and the n-type region is disposed between the oxide layer and the III-nitride light emitting layer.

2. The device of claim 1 wherein the first and second III-nitride layers have different in-plane lattice constants.

3. The device of claim 1 wherein at least one of the first and second III-nitride layers has an in-plane lattice constant of at least 3.195 Å.

4. The device of claim 1 wherein the first III-nitride layer is GaN and the second III-nitride layer is one of InGaN, AlGaN, and AlInGaN.

5. The device of claim 1 wherein the n-type region has an InN composition of not more than 5% and the light emitting layer has an InN composition of not more than 10%.

6. The device of claim 1 wherein the n-type region has an InN composition of not more than 10% and the light emitting layer has an InN composition of not more than 20%.

7. The device of claim 1 wherein the n-type region has a same InN composition as the light emitting layer.

8. The device of claim 7 further comprising a barrier layer disposed between the n-type region and the light emitting layer, wherein the barrier layer has a smaller InN composition than the light emitting layer.

9. The device of claim 1 wherein the oxide layer and the first and second III-nitride layers form a distributed Bragg reflector.

10. The device of claim 1 wherein the oxide layer comprises at least one oxide of aluminum.

11. The device of claim 1 further comprising first and second contacts electrically connected to the n-type and p-type regions.

12. The device of claim 1 further comprising a mount, wherein the semiconductor structure is connected to the mount by first and second contacts electrically connected to the n- and p-type regions, wherein the first and second contacts are both formed on a same side of the semiconductor structure.

13. The device of claim 1 wherein the oxide layer is a first oxide layer, the device further comprising a second oxide layer disposed between the second III-nitride layer and a third III-nitride layer.

14. The device of claim 13 wherein an in-plane lattice constant of the third III-nitride layer is greater than an in-plane lattice constant of the second III-nitride layer.

15. The device of claim 13 wherein the third III-nitride layer is one of InGaN, AlGaN, and AlInGaN.

16. The device of claim 13 wherein the first and second oxide layers each comprise at least one oxide of aluminum.

17. The device of claim 13 further comprising first and second contacts electrically connected to the n-type and p-type regions.

18. The device of claim 13 further comprising a mount, wherein the semiconductor structure is connected to the mount by first and second contacts electrically connected to the n- and p-type regions, wherein the first and second contacts are both formed on a same side of the semiconductor structure.

19. A method comprising:
growing a first III-nitride layer over a growth substrate;
growing a second III-nitride layer over the first III-nitride layer;
growing device layers over the second III-nitride layer, the device layers comprising a III-nitride light emitting layer disposed between an n-type region and a p-type region; and
oxidizing the second III-nitride layer.

20. The method of claim 19 further comprising:
prior to oxidizing the second III-nitride layer, etching a portion of the device layers to expose the second III-nitride layer.

21. The method of claim 19 wherein the second III-nitride layer is AlInN.

22. The method of claim 19 further comprising removing the growth substrate from the device layers.

23. The method of claim 22 further comprising etching the first III-nitride layer by a process that etches the first III-nitride layer at a rate different from the oxidized second III-nitride layer.

24. The method of claim 22 wherein removing the growth substrate comprises etching the oxidized second III-nitride layer.

25. The method of claim 24 wherein a III-nitride layer exposed by removing the growth substrate has a substantially constant thickness over a lateral extent of the exposed III-nitride layer.

26. A device comprising:
a semiconductor structure comprising a light emitting layer disposed between an n-type region and a p-type region; and
an oxide layer, wherein the oxide layer separates first and second semiconductor layers;
wherein one of the p-type or the n-type region is disposed between the oxide layer and the light emitting layer.

27. The device of claim 26 wherein the first and second semiconductor layers have different in-plane lattice constants.

28. The device of claim 26 wherein the semiconductor structure comprises a plurality of layers of III-V or II-VI material.

29. The device of claim 26 wherein the oxide layer comprises an oxide of one of AlInGaAs, AlAs, AlGaAs, AlInAs, AlInGaSb, AlAsSb, AlSb, AlGaSb, AlInSb, AlInGaP, AlP, AlGaP, and AlInP.

30. The device of claim 26 wherein one of the first and second semiconductor layers comprises one of AlInGaP, InGaP, GaP, InP, GaAsP, AlInGaAsP, AlInGaAs, InGaAs InAs,GaAs, AlGaInSb, GaSb, InSb, GaInSb, GaSbAs, ZnO, ZnS, ZnSe, ZnTe, CdS, CdSe, CdTe, HgS, HgSe, and HgTe.
